(19) United States
(12) Patent Application Publication
(10) Pub. No.: US 2017/0356891 A1
(43) Pub. Date: Dec. 14, 2017

(54) METHOD AND APPARATUS FOR MEASURING CONCENTRATION OF OXIDANT AND SYSTEM FOR CLEANING ELECTRONIC MATERIAL

(71) Applicant: KURITA WATER INDUSTRIES LTD., Tokyo (JP)

(72) Inventors: Hiroshi MORITA, Tokyo (JP); Yuichi OGAWA, Tokyo (JP); Yuya SASAKI, Tokyo (JP)

(21) Appl. No.: 15/540,807

(22) PCT Filed: Jan. 6, 2016
(86) PCT No.: PCT/JP2016/050216

§ 371 Date: Jun. 29, 2017

(30) Foreign Application Priority Data
Jan. 14, 2015 (JP) 2015-005079
Jan. 6, 2016 (JP) 2016-000821

(51) Int. Cl. G01N 31/12; B08B 3/08; B08B 3/14; H01L 21/67

(52) U.S. Cl. CPC G01N 31/12; B08B 3/14; B08B 3/08; H01L 21/67276; H01L 21/67051

(57) ABSTRACT

To measure the concentration of an oxidant in an oxidative cleaning liquid used in a process of cleaning an electronic material in a simple, easy, consistent, and accurate manner without being affected by impurities included in the cleaning liquid, such as metals. A method for measuring the concentration of an oxidant in a sample liquid used as a cleaning liquid in a process of cleaning an electronic material includes decomposing at least part of an oxidant included in the sample liquid by heating or the like; measuring the amount of oxygen gas generated by decomposition of the oxidant; and determining the concentration of the oxidant in the sample liquid on the basis of the amount of the oxygen gas.

### TECHNICAL FIELD

The present invention relates to a technique for measuring the concentration of an oxidant in a cleaning liquid used in a process of cleaning an electronic material such as a semiconductor or an electronic display (e.g., a liquid-crystal display, a plasma display, or an organic EL).

### BACKGROUND ART

When the surface of an electronic material is cleaned (e.g., removal of residues or etching) using an oxidative cleaning chemical liquid, it is necessary to control the concentration of an oxidant in the cleaning liquid, which is the measure of oxidizing power. The concentration of an oxidant in a cleaning liquid has been determined by an offline analysis in which a liquid is sampled and the concentration of an oxidant in the sample liquid is measured by titration or the like. However, in processes that require high productivity and high accuracy, such as etching of the surfaces of semiconductor wafers, there has been a strong demand for an instantaneous control of the concentration of the oxidant in the cleaning liquid by continuous monitoring.

In JP2004-67469A and JP2008-58591A, a method in which the concentration of an oxidizing substance is monitored by using the absorbance of ultraviolet light is described.

The monitoring method using the absorbance of ultraviolet light has the following issues. Specifically, in the case where a waste cleaning liquid is reused, accurate monitoring may fail to be performed by using the absorbance of ultraviolet light, because impurities included in the waste cleaning liquid affect the measured value. For example, in oxidant monitors using ultraviolet light which have been used in a process of cleaning semiconductor wafers with an SPM solution (a solution including sulfuric acid and hydrogen peroxide), if metal components dissolved from the surfaces of wafers mix into the SPM solution, the metal components affect the absorbance measured by the oxidant monitors and make it impossible to determine the concentration of an oxidant accurately.

In WO2015/012041, a method in which the overall concentration of oxidizing substances in the electrolyzed sulfuric acid is determined from a measured absorbance is described.

In JP2012-184951A, a method in which a liquid containing an oxidizing substance such as a persulfuric acid salt is heated and the concentration of the oxidizing substance is determined by detecting hydrogen peroxide produced by the pyrolysis of the liquid is described. In JP2010-127830A, a method in which hydrogen peroxide included in a sample solution is decomposed with a catalyst, the concentration of dissolved oxygen is subsequently measured, and the concentration of hydrogen peroxide is determined from the results of the measurement of the concentration of dissolved oxygen is described.
PTL 1: JP2004-67469A
PTL 2: JP2008-58591A
PTL 3: WO2015/012041
PTL 4: JP2012-184951A
PTL 5: JP2010-127830A

### SUMMARY OF INVENTION

An object of the present invention is to provide a method and an apparatus for measuring the concentration of an oxidant in an oxidative cleaning liquid used in a process of cleaning an electronic material in a simple, easy, consistent, and accurate manner without being affected by impurities included in the cleaning liquid, such as metals, and a system for cleaning an electronic material that includes the apparatus for measuring the concentration of an oxidant.

The summary of the present invention is as follows.

[1] A method for measuring a concentration of an oxidant in a sample liquid used as a cleaning liquid in a process of cleaning an electronic material, the method comprising:

decomposing at least part of an oxidant included in the sample liquid;

measuring an amount of released gas generated by decomposition of the oxidant, the released gas including oxygen gas; and

determining the concentration of the oxidant in the sample liquid based on the amount of the released gas.

[2] The method for measuring a concentration of an oxidant according to [1], wherein the sample liquid is successively introduced to decomposing device for decomposing the oxidant, the decomposing device discharging the released gas including oxygen gas, and wherein the concentration of the oxidant in the sample liquid is determined from a flow rate of the sample liquid and a flow rate of the released gas.

[3] The method for measuring a concentration of an oxidant according to [1] or [2], wherein the oxidant is decomposed by using at least one selected from heating, ultraviolet radiation, ultrasound, and a catalyst.

[4] The method for measuring a concentration of an oxidant according to [3], wherein the sample liquid is a sulfuric acid solution including an oxidant, the concentration of sulfuric acid in the sulfuric acid solution being 85% by weight or more, and wherein the oxidant is decomposed by performing heating at 150° C. or more.

[5] The method for measuring a concentration of an oxidant according to any one of [1] to [4], wherein, subsequent to decomposing the oxidant included in the sample liquid, the released gas is subjected to vapor-liquid separation, and an amount of resulting separated gas is measured.

[6] The method for measuring a concentration of an oxidant according to [5], wherein, subsequent to the vapor-liquid separation, vapor and mist included in the separated gas are removed by cooling the gas.

[7] The method for measuring a concentration of an oxidant according to [6], wherein the vapor and mist included in the separated gas are removed by passing the separated gas through a layer filled with a filler.

[8] The method for measuring a concentration of an oxidant according to any one of [1] to [7], wherein the sample liquid includes at least one selected from a soluble organic substance, undissolved SS, and metal ions.

[9] The method for measuring a concentration of an oxidant according to any one of [1] to [8], wherein part of the cleaning liquid fed to the process of cleaning an electronic material is taken, as a sample liquid, from a liquid-feeding system for feeding the cleaning liquid, and, subsequent to measuring the concentration of the oxidant in the sample liquid, the sample liquid is returned to the liquid-feeding system at a position upstream of a position at which the sample liquid is taken from the liquid-feeding system.

[10] The method for measuring a concentration of an oxidant according to any one of [1] to [9], wherein, in the process of cleaning an electronic material, a waste cleaning liquid is recycled and reused as the cleaning liquid.

[11] The method for measuring a concentration of an oxidant according to any one of [1] to [10], the method including a measurement step in which the concentration of the oxidant in the sample liquid is measured while the sample liquid is successively introduced to the device for decomposing the oxidant; and a non-measurement step in which introduction of the sample liquid to the device for decomposing the oxidant is stopped, wherein, in the non-measurement step, a replacement liquid is introduced to the device for decomposing the oxidant.

[12] The method for measuring a concentration of an oxidant according to [11], wherein the device for decomposing the oxidant performs heating in order to decompose the oxidant and continues the heating even in the non-measurement step.

[13] The method for measuring a concentration of an oxidant according to [11] or [12], wherein a difference in liquid composition between the replacement liquid and the sample liquid is 30% or less of a liquid composition of the sample liquid.

[14] An apparatus for measuring a concentration of an oxidant in a sample liquid used as a cleaning liquid in a process of cleaning an electronic material, the apparatus comprising:

oxidant-decomposing device for decomposing at least part of the oxidant included in a sample liquid;

a released-gas-measuring device for measuring an amount of released gas generated by decomposition of the oxidant, the released gas including oxygen gas; and

a computing device for determining the concentration of the oxidant in the sample liquid based the amount of the released gas measured by the released-gas-measuring device.

[15] The apparatus for measuring a concentration of an oxidant according to [14], the apparatus further comprising:

an introduction pipe through which the sample liquid is introduced to the oxidant-decomposing device;

a liquid-flow meter disposed in the introduction pipe;

an exhaust pipe through which released gas generated in the oxidant-decomposing device is exhausted; and

a gas-flow meter disposed in the exhaust pipe, the computing device determining the concentration of the oxidant based on a value measured with the liquid-flow meter and a value measured with the gas-flow meter.

[16] The apparatus for measuring a concentration of an oxidant according to [14] or [15], wherein the oxidant-decomposing device employs at least one decomposition system selected from heating, ultraviolet radiation, ultrasound, and a catalyst.

[17] The apparatus for measuring a concentration of an oxidant according to any one of [14] to [16], wherein the sample liquid is a sulfuric acid solution including an oxidant, the concentration of sulfuric acid in the sulfuric acid solution being 85% by weight or more, and wherein the oxidant-decomposing device performs heating at 150° C. or more.

[18] The apparatus for measuring a concentration of an oxidant according to any one of [14] to [17], the apparatus further comprising a vapor-liquid separation device in which the released gas discharged from the oxidant-decomposing device is subjected to vapor-liquid separation, a separated gas produced in the vapor-liquid separation device being fed to the released-gas-measuring means.

[19] The apparatus for measuring a concentration of an oxidant according to [18], the apparatus further comprising a gas-purifying device for removing vapor and mist included in the separated gas produced in the vapor-liquid separation device by cooling the separated gas, gas purified in the gas-purifying device being fed to the released-gas-measuring device.

[20] The apparatus for measuring a concentration of an oxidant according to [19], wherein the gas-purifying device includes a layer filled with a filler.

[21] The apparatus for measuring a concentration of an oxidant according to any one of [18] to [20], the apparatus further comprising a device for cooling a separated liquid produced in the vapor-liquid separation device.

[22] The apparatus for measuring a concentration of an oxidant according to any one of [14] to [21], the apparatus further comprising:

a replacement-liquid tank for storing a replacement liquid introduced to the oxidant-decomposing device instead of the sample liquid; and

a first introduction pipe through which the replacement liquid stored in the replacement-liquid tank is introduced to the oxidant-decomposing device.

[23] The apparatus for measuring a concentration of an oxidant according to [22],

wherein the oxidant-decomposing device decomposes the oxidant by performing heating,

wherein the apparatus further comprises a switching device with which the introduction of the liquid is switched between a second introduction pipe through which the sample liquid is introduced to the oxidant-decomposing device and the first introduction pipe through which the replacement liquid stored in the replacement-liquid tank is introduced to the oxidant-decomposing device, and

wherein the oxidant-decomposing device continues heating even while the replacement liquid is introduced to the oxidant-decomposing device.

[24] The apparatus for measuring a concentration of an oxidant according to [22] or [23], wherein the difference in liquid composition between the replacement liquid and the sample liquid is 30% or less of the liquid composition of the sample liquid.

[25] A system for cleaning an electronic material, the system comprising:

a device for cleaning an electronic material;

a cleaning-liquid-feeding device for feeding a cleaning liquid to the cleaning device;

a liquid-sampling device for taking part of the cleaning liquid as a sample liquid from the cleaning-liquid-feeding device; and

an oxidant-concentration-measuring device for that measuring a concentration of an oxidant in the sample liquid taken by the liquid-sampling device, the oxidant-concentration-measuring device including the apparatus for measuring a concentration of an oxidant according to any one of [14] to [24].

[26] The system for cleaning an electronic material according to [25], the system further comprising a sample-liquid-returning device that returns, subsequent to the measurement of the concentration of an oxidant by the oxidant-concentration-measuring device, the sample liquid taken by the liquid-sampling device to a position upstream of a position at which the sample liquid is taken from the cleaning-liquid-feeding device.

[27] The system for cleaning an electronic material according to [26], wherein the oxidant-concentration-measuring device includes the apparatus for measuring a concentration of an oxidant according to [21], and wherein the system further comprises a vessel that stores a liquid cooled by the device for cooling the separated liquid, the liquid stored in the storage vessel being returned by the sample-liquid-returning device.

[28] The system for cleaning an electronic material according to any one of [25] to [27], the system further comprising:

a recycling device for recycling a waste cleaning liquid that has been used for cleaning in the cleaning device; and

a circulation device for feeding a liquid recycled in the recycling device to the cleaning device, the liquid being reused as a cleaning liquid.

### Advantageous Effects of Invention

The method and the apparatus for measuring the concentration of an oxidant according to the present invention enable the concentration of an oxidant in an oxidative cleaning liquid used in a process of cleaning an electronic material in a simple, easy, consistent, and accurate manner without being affected by impurities included in the cleaning liquid, such as metals. The measurement technique according to the present invention enables online continuous monitoring to be readily achieved.

The system for cleaning an electronic material according to the present invention enables efficient cleaning with a cleaning liquid having a predetermined concentration of an oxidant to be achieved by using the above measurement technique.

### BRIEF DESCRIPTION OF DRAWINGS

FIG. 1 a system diagram illustrating an example of an apparatus for measuring the concentration of an oxidant according to an embodiment of the present invention.

FIG. 2 is a schematic cross-sectional view of moisture-removal means, illustrating an example of the structure of the moisture-removal means.

FIG. 3 is a system diagram illustrating an example of a system for cleaning an electronic material according to an embodiment of the present invention.

FIG. 4 is a system diagram illustrating another example of a system for cleaning an electronic material according to an embodiment of the present invention.

FIG. 5 is a system diagram illustrating another example to which the apparatus for measuring the concentration of an oxidant according to the present invention is applied.

FIG. 6 is a system diagram illustrating another example of an apparatus for measuring the concentration of an oxidant according to an embodiment of the present invention.

### DESCRIPTION OF EMBODIMENTS

Embodiments of the present invention are described below in detail.

In the present invention, an oxidant included in a sample liquid is decomposed, the amount of released gas including oxygen gas which is generated by the decomposition of the oxidant is measured, and the concentration of the oxidant in the sample liquid is determined on the basis of the measured value. The mechanisms of the above measurement are described below.

Oxidants are classified into the following two groups, which both generate oxygen by pyrolysis or the like. It is possible to determine the concentration of an oxidant in a sample liquid by measuring the amount of gas generated by decomposition and released from the liquid.

(1) Oxidants that include oxygen and generate oxygen when decomposed.

Oxidants such as persulfuric acid, hydrogen peroxide, a permanganate, chromic acid, a peroxide, and potassium nitrate.

For example, a permanganate decomposes as in the reaction formula below to produce oxygen.

MnO₄→Mn+2O₂

(2) Substances that serve as an oxidant in terms of electron transfer. These oxidants react in water to form a peroxide, which produces oxygen when decomposed.

Oxidants such as halogens and Tollens' reagent.

For example, chlorine decomposes as in the reaction formula below to produce oxygen gas.

Cl₂+2H₂O→2HClO→2HCl+O₂

Since a cleaning liquid used in the process of cleaning an electronic material, a waste cleaning liquid, and a reused cleaning liquid produced by recycling the waste cleaning liquid substantially do not contain an organic substance (TOC) that consumes an oxidant, according to the present invention, it is possible to accurately determine the concentration of an oxidant.

The method according to the present invention may be applied to both batch-mode measurement and continuous monitoring. In particular, applying the method according to the present invention to continuous monitoring is advantageous from an industrial viewpoint, because it enables the concentration of an oxidant in a cleaning liquid to be instantaneously measured and reflected in the cleaning process.

Means for decomposing the oxidant may be selected depending on the type of the oxidant. Examples of the means for decomposing the oxidant include heating, ultraviolet irradiation, ultrasound irradiation, and contact with a catalyst. The above means may be used in combination. Examples of the combination include a combination of heating means and ultraviolet radiation and a combination of preheating means and ultrasound irradiation. In particular, in the case where the sample liquid is a sulfuric-acid-based oxidant solution, heating a sulfuric-acid-based oxidant solution containing 85% or more of sulfuric acid, which can be heated at high temperatures, to 150° C. or more enables the oxidant included in the solution to be decomposed in a short time. If the concentration of sulfuric acid is less than 85% by weight, the boiling point of the solution becomes excessively low, which makes it difficult in principle to pyrolyze the oxidant to a required decomposition percentage in a short time. As a result, other decomposing means needs to be used in combination.

It is desirable to decompose most (e.g., 90% or more, preferably 95% or more) of the oxidant included in the sample liquid in consideration of the accuracy of measurement. Even when the decomposition percentage is low (e.g., about 80%), it is possible in principle to conduct the measurement when the decomposition is performed within a few minutes and the decomposition percentage is consistent.

A method for determining the concentration of an oxidant in a sample liquid from the amount of released oxygen gas according to the present invention is described below.

### [Example Case 1] Electrolyzed Sulfuric Acid

The concentration of all oxidants included in a sample liquid is determined as the concentration of any one of the oxidants included in the sample liquid.

The number of moles of the oxidant included in the sample liquid that is to be measured per unit time is determined using the following expression.

Number of moles of oxidant [mol/min]=Flow rate of sample liquid [mL/min]×Concentration of oxidants [g/L]×10⁻³/Molecular weight

When the number of moles of oxygen (oxygen atoms) produced from the oxidant when the oxidant is completely decomposed is n times the number of moles of the oxidant, the number of moles of oxygen gas (O₂ molecules) produced by the decomposition of the oxidant per unit time is determined using the following expression.

Number of moles of oxygen gas [mol/min]=Number of moles of oxidant [mol/min]×n/2

The flow rate (mL/min) of the oxygen gas under the standard state conditions (1 atm) is determined as follows by converting the amount of the oxygen gas into volume.

Flow rate of oxygen gas [mL/min]=Number of moles of oxygen gas [mol/min]×22.4

On the basis of the above relationships, the concentration of the oxidant is determined using the following expression.

Concentration of oxidant [g/L]=(Flow rate of oxygen gas [mol/min]×Molecular weight×2)/(Flow rate of sample liquid [mol/min]×n×22.4)

In the case where the sample liquid is electrolyzed sulfuric acid, the oxidant included in electrolyzed sulfuric acid is substantially persulfuric acid (mixture of peroxydisulfuric acid and peroxomonosulfuric acid). Therefore, the concentration of the oxidants may be determined as the concentration of peroxydisulfuric acid. Since the number of moles of oxygen produced as oxygen gas when peroxydisulfuric acid is completely decomposed is the same as the number of moles of peroxydisulfuric acid used, the concentration of the oxidant is determined using the following expression.

Concentration of oxidant [g/L as S₂O₈²⁻]=(Flow rate of oxygen gas [mL/min]×Molecular weight of S₂O₈²⁻: 192×2)/(Flow rate of sample liquid [mL/min]×1×22.4)

In the case where the oxidant is not completely decomposed, correction may be made by multiplying the concentration of the oxidant by the decomposition percentage (%) of the oxidant.

### [Example Case 2] Ammonia-Hydrogen Peroxide Mixture

A diluted APM solution (ammonia-hydrogen peroxide mixture: aqueous solution containing ammonia and hydrogen peroxide) is used, for example, such that a 28-weight % ammonia water reagent: a 30-weight % hydrogen peroxide water reagent: ultrapure water=1:4:95 (volume ratio). The concentration of oxidants in an APM solution is determined assuming that the whole amount of the oxidants is the amount of hydrogen peroxide.

The mass of H₂O₂ included in 1 L of the APM solution is:

(1 L×4/100)×specific gravity: 1≈40 g (specific gravity is considered to be 1 since the APM solution is principally constituted by water)

The number of moles of H₂O₂ is:

40 g×30 weight %/Molecular weight of H₂O₂: 34=0.35 [mol-H₂O₂]

Since the amount of oxygen produced as oxygen gas when H₂O₂ is completely decomposed is the same as the amount of H₂O₂ used as in the above Example Case 1, the number of moles of the produced oxygen gas is:

0.35 [mol-H₂O₂]×½=0.18[mol-O₂]

Thus, the number of moles of the oxygen gas converted into volume is:

0.18 [mol-O₂]×22.4≈4.0 [L-O₂]

On the basis of the above relationships, the concentration of the oxidant is determined using the following expression.

Concentration of oxidant [g/L as H₂O₂]=(Flow rate of oxygen gas [mL/min]×Molecular weight of H₂O₂: 34×2)/(Flow rate of sample liquid [mL/min]×1×22.4)

### [Example Case 3] SPM Solution

An SPM solution (sulfuric acid-hydrogen peroxide mixture) primarily includes two oxidants: peroxomonosulfuric acid and hydrogen peroxide.

The concentration of the oxidants in the SPM solution is determined assuming that the whole amount of the oxidants is the amount of hydrogen peroxide as in the above Example Case 2.

Although the difficulty in the decomposition of the oxidants varies with the mixing ratio, a decomposition percentage of 75% or more is achieved when 30-weight % hydrogen peroxide:96-weight % sulfuric acid=1:4 to 1:50 (by volume). Examples of possible conditions under which the oxidants are decomposed until the decomposition percentage reaches 75% or more include heating (150° C. or more and preferably 180° C. or more), a decomposition catalyst, and a combination of heating and ultraviolet irradiation.

In the case where an SPM solution is used, hydrogen peroxide is added to the SPM solution every time the SPM solution is recycled and reused and, as a result, the concentrations of sulfuric acid and peroxomonosulfuric acid are reduced in a manner opposite to the case where electrolyzed sulfuric acid is used. It is preferable in the present invention to measure the concentration of oxidants included in an unused SPM solution immediately after fresh sulfuric acid and hydrogen peroxide are mixed with each other. It is also possible in principle to determine the timing of replacement of an SPM solution by measuring the concentration of oxidants in the SPM solution while the SPM solution is recycled and reused.

The percentage at which an oxidant is decomposed by the means for decomposing an oxidant can be calculated from the concentration of the oxidant in a sample liquid before decomposition and the concentration of the oxidant in the sample liquid after decomposition which are measured by a preliminary test conducted under predetermined conditions. In Examples below, for example, the decomposition percentage achieved using a pyrolyzer is about 75% when the heating temperature is 180° C. and the retention time is 12.5 minutes, is about 90% when the heating temperature is 200° C. and the retention time is 5 minutes, and is 95% to 100% when the heating temperature is 200° C. and the retention time is 12.5 minutes.

Thus, the concentration of the oxidant in a sample liquid can be determined by dividing the amount of released oxygen gas by the decomposition percentage.

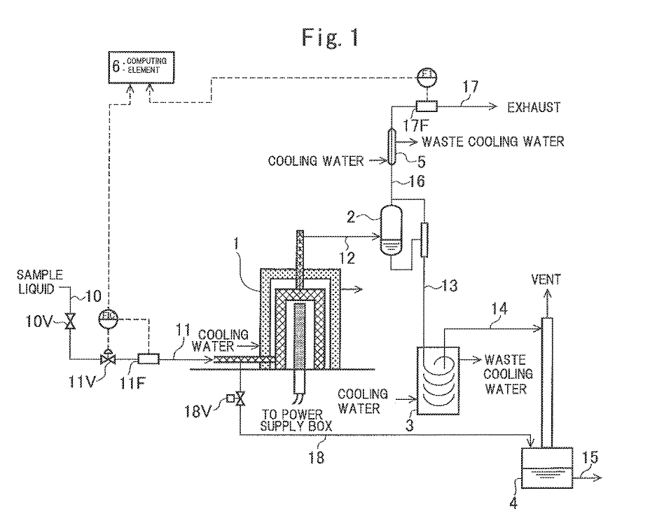

An apparatus for measuring the concentration of an oxidant according to the present invention is described below with reference to FIG. 1.

FIG. 1 a system diagram illustrating an example of the apparatus for measuring the concentration of an oxidant according to an embodiment of the present invention, where Reference Numeral 1 denotes a pyrolyzer; Reference Numeral 2 denotes a vapor-liquid separator; Reference Numeral 3 denotes a separated-liquid cooler; Reference Numeral 4 denotes a separated-liquid return tank; Reference Numeral 5 denotes a gas cooler; and Reference Numeral 6 denotes a computing element.

A sample liquid taken from, for example, a process of cleaning an electronic material and fed through a pipe 10 is introduced to the pyrolyzer 1 through a pipe 11. A decomposed liquid produced in the pyrolyzer 1 as a result of the decomposition of an oxidant is fed to the vapor-liquid separator 2 through a pipe 12 and subjected to vapor-liquid separation. A separated liquid produced in the vapor-liquid separator 2 is fed to the separated-liquid cooler 3 through a pipe 13 to be cooled and subsequently discharged through a pipe 14, the separated-liquid return tank 4, and a pipe 15. The discharged liquid is returned to the process of cleaning an electronic material or the like. Reference Numeral 10V denotes an on-off valve disposed in the pipe 10.

A separated gas produced in the vapor-liquid separator 2 is fed to the gas cooler 5 through a pipe 16, cooled in the gas cooler 5, and subsequently discharged through a pipe 17.

The pipe 11 through which a sample liquid is introduced is provided with a flow-rate-controlling valve 11V and a liquid-flow meter 11F that are disposed therein. Values measured by the liquid-flow meter 11F are sent to the computing element 6. The gas exhaust pipe 17 is provided with a gas-flow meter 17F disposed therein. Values measured by the gas-flow meter 17F are sent to the computing element 6. The computing element 6 calculates the concentration of an oxidant from the flow rate of the sample liquid and the flow rate of the released gas in accordance with the expression described above.

In the embodiment illustrated in FIG. 1, the pyrolyzer 1 is a liquid heater having a double-pipe structure. The pyrolyzer 1 decomposes most of the oxidant included in the sample liquid by heating the sample liquid to 150° C. or more, preferably 180° C. or more, and more preferably 180° C. to 220° C. A fluid that is a gas-liquid mixture containing oxygen gas produced by the decomposition of the oxidant is fed to the vapor-liquid separator 2 and subjected to vapor-liquid separation. It is necessary to perform heating at a high temperature as described above for decomposing most of the oxidant by pyrolysis, although the temperature depends on the type of oxidant. It is necessary to complete the decomposition in a short time for applying the apparatus for measuring the concentration of an oxidant to practical use as an oxidant-concentration-measuring means capable of continuous monitoring. It is preferable to rapidly increase the temperature to a predetermined temperature by a heating method in which a sample liquid is rapidly heated with a lamp heater or the like from the inside of a double-pipe channel having a small width, such as the pyrolyzer 1, while the sample liquid is passed upwardly through the double-pipe channel.

The apparatus illustrated in FIG. 1 is merely an example of the apparatus for measuring the concentration of an oxidant according to an embodiment of the present invention. The apparatus for measuring the concentration of an oxidant according to the present invention is not limited to that illustrated in FIG. 1 without departing from the scope of the present invention. For example, the means for decomposing an oxidant may be, instead of a pyrolyzer, a catalyst-packed column, an ultraviolet irradiation device, an ultrasound irradiation device, or a combination of these apparatuses.

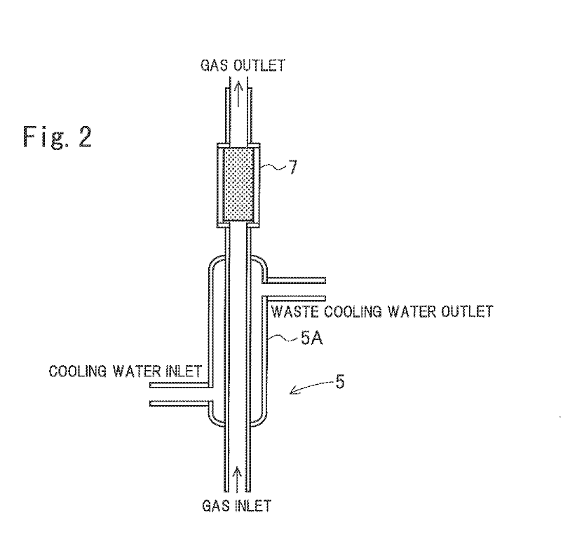

The gas cooler 5 removes vapor and mist, such as moisture, from the separated gas by cooling the gas and condensing the vapor and mist. An example of the gas cooler is the water-cooling jacket 5A illustrated in FIG. 2. As illustrated in FIG. 2, a demister 7 including a layer filled with a filler may be disposed downstream of the gas cooler 5 (i.e., above the gas cooler 5, since the gas flows upwardly in FIG. 2). Providing the demister 7 enables mist to be removed with further certainty.

The reasons for providing the gas cooler 5 and the demister 7 are as follows.

The separated gas produced by vapor-liquid separation contains vapor and mist, such as moisture and acids, which originate from the sample liquid. If the separated gas containing moisture is introduced to the gas-flow meter, the flow rate of the gas is increased. This causes error of measurement and increases the risk of moisture condensing in the measuring instrument. For example, in the case where a sample liquid includes sulfuric acid, the separated gas contains a trace amount of sulfuric acid vapor or sulfuric acid mist. When the separated gas containing sulfuric acid is introduced to the gas-flow meter, the separated gas is cooled while being introduced to the flow meter and forms a condensate containing a high concentration of sulfuric acid. If the condensate enters the gas-flow meter, it may significantly corrode the gas-flow meter. In order to prevent the above problems from occurring, it is desirable to purify the separated gas in advance by removing the vapor and mist, such as moisture and acids.

Another example of the gas-purifying means may be means including a container containing pure water, the means removing impurities such as acid components by introducing the separated gas to the container and causing the impurities to elute toward water at the gas-liquid interfaces of gas bubbles. Providing a dehumidification film capable of separating and removing moisture from the purified gas eliminates the risk of adverse effects to the gas-flow meter, which is disposed downstream of the gas-purifying means.

Maintaining the temperature of the gas fed to the gas-flow meter to be within a predetermined range increases the accuracy of measurement. Using the gas cooler 5 is preferable also in this regard.

In the apparatus for measuring the concentration of an oxidant illustrated in FIG. 1, the sample liquid introduced to the pyrolyzer 1 is fed from, for example, a persulfuric-acid-feeding device (hereinafter, may be referred to as “ESA unit”). Feeding of the sample liquid is stopped during the maintenance of the ESA unit, such as replacement of the liquid contained in the ESA unit. In such a case, the liquid contained in the apparatus is removed, and the operation of the apparatus is stopped. The operation of the apparatus is restarted when the ESA unit is restarted and feeding of the sample liquid is restarted.

When the liquid contained in the apparatus is removed and heating of the pyrolyzer 1 is stopped upon the introduction of the sample liquid being stopped and, subsequently, the sample liquid is introduced to the pyrolyzer 1 and heating of the pyrolyzer 1 with a heater is restarted upon the introduction of the sample liquid is restarted, the amount of oxygen gas released when the operation of the apparatus is restarted is increased due to rapid decomposition of an oxidant contained in the pyrolyzer 1. This increases the gas pressure inside the system and the apparent concentration of the oxidant. Therefore, it takes a large amount of time to conduct normal measurement, that is, start the apparatus.

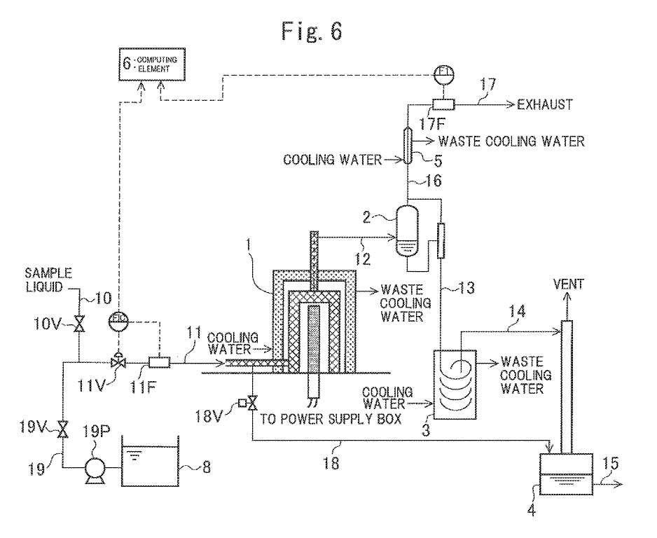

In order to address the above issues, the apparatus for measuring the concentration of an oxidant illustrated in FIG. 6 includes a replacement-liquid tank 8 such that, while the introduction of the sample liquid is stopped, heating of the pyrolyzer 1 is continued by introducing a replacement liquid from the replacement-liquid tank 8 to the pyrolyzer 1 through an introduction pipe 19 instead of the sample liquid. The apparatus for measuring the concentration of an oxidant illustrated in FIG. 6 has the same structure as the apparatus for measuring the concentration of an oxidant illustrated in FIG. 1, except that the apparatus illustrated in FIG. 6 includes the replacement-liquid tank 8 and the introduction pipe 19. Members having the same function are denoted by the same reference numeral.

In this apparatus for measuring the concentration of an oxidant, upon the valve 10V being closed in order to stop feeding of the sample liquid, the replacement liquid contained in the replacement-liquid tank 8 is introduced to the pyrolyzer 1 instead of the sample liquid by opening a valve 19V and actuating a pump 19P. When feeding of the sample liquid is to be restarted, the introduction of the replacement liquid is stopped and the introduction of the sample liquid is restarted by opening the valve 10V, closing the valve 19V, and stopping the pump 19P. Feeding the replacement liquid instead of the sample liquid while feeding of the sample liquid is stopped prevents the pyrolyzer 1 from being heated without a liquid contained therein when heating of the pyrolyzer 1 is continued and reduces the risk of the pyrolyzer 1 being excessively heated when the introduction of the sample liquid is restarted. This markedly reduces the amount of start-up time required to stabilize the amount of oxygen gas released compared with the case where the replacement liquid is not introduced.

The replacement liquid introduced to the pyrolyzer 1 instead of the sample liquid preferably has a liquid composition substantially equal to that of the sample liquid in order to continue the operation of the apparatus both while the replacement liquid is passed through the pyrolyzer 1 and while the sample liquid is passed through the pyrolyzer 1 under the similar operating conditions and, as a result, further reduce the amount of start-up time. The flow rate at which the replacement liquid is passed through the pyrolyzer 1 is preferably substantially equal to that at which the sample liquid is passed through the pyrolyzer 1 in the operation in which the concentration of the oxygen gas is measured.

The liquid composition substantially equal to that of the sample liquid is a liquid composition smaller or larger than the liquid composition of the sample liquid by 30% or less. For example, in the case where the concentration of an oxidant in the sample liquid is A % by weight, it is preferable that the replacement liquid include the same oxidant as the sample liquid and the concentration of the oxidant in the replacement liquid be A×(0.7 to 1.3) % by weight and be particularly A×(0.9 to 1.1) % by weight.

It is also preferable that the flow rate of the replacement liquid be B×(0.7 to 1.3) mL/min and particularly preferably B×(0.9 to 1.1) mL/min, where B [mL/min] represents the flow rate of the sample liquid in the measurement of the concentration of the oxygen gas.

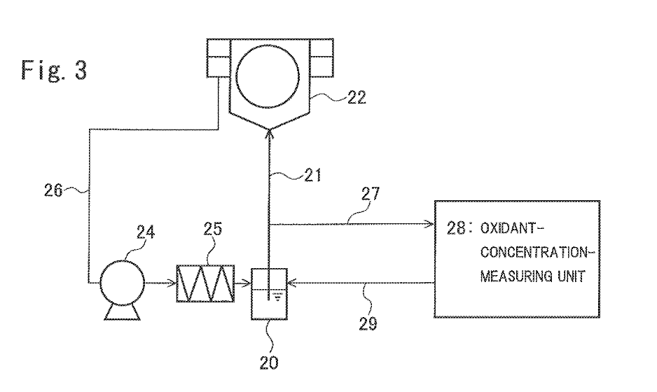

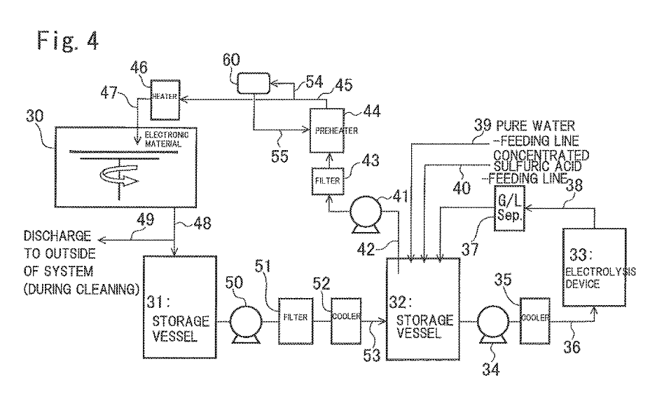

A system for cleaning an electronic material which includes the apparatus for measuring the concentration of an oxidant according to the present invention is described below with reference to FIGS. 3 and 4.

FIGS. 3 and 4 are system diagrams each illustrating a system for cleaning an electronic material which includes the apparatus for measuring the concentration of an oxidant according to the present invention.

FIG. 3 illustrates a system for cleaning an electronic material in which the apparatus for measuring the concentration of an oxidant according to the present invention is used in combination with a batch cleaning machine. A cleaning liquid contained in the cleaning-liquid storage vessel 20 is fed to a cleaning machine 22 through a pipe 21. The resulting waste cleaning liquid is returned to the storage vessel 20 through a pipe 26 provided with a pump 24 and a heat exchanger 25 that are disposed therein. A liquid-sampling pipe 27, through which part of the cleaning liquid fed to the cleaning machine 22 is taken as a sample liquid, is branched from the pipe 21. The sample liquid taken through the pipe 27 is fed to an oxidant-concentration-measuring unit 28 that is the apparatus for measuring the concentration of an oxidant according to the present invention, in which the concentration of an oxidant in the sample liquid is measured. The sample liquid that has been used for the measurement (e.g., the liquid contained in the separated-liquid return tank 4 included in the apparatus for measuring the concentration of an oxidant illustrated in FIG. 1) is returned to the storage vessel 20 through a pipe 29.

When the sample liquid that has been used for the measurement of the concentration of an oxidant is returned to the process of cleaning an electronic material, it is preferable to return the used sample liquid at a position upstream of the position at which the sample liquid is taken, because this makes it easy to return the used sample liquid to the electronic-material-cleaning process.

FIG. 4 illustrates an example of a system for cleaning an electronic material which includes a persulfuric acid-feeding system that produces peroxydisulfuric acid by the electrolysis of a sulfuric acid solution and feeds the sulfuric acid solution containing peroxydisulfuric acid to the cleaning system, the cleaning system including the apparatus for measuring the concentration of an oxidant according to the present invention. In FIG. 4, Reference Numeral 30 denotes a single-wafer electronic-material-cleaning device; Reference Numeral 31 denotes a storage vessel that stores an unused-cleaning liquid; Reference Numeral 32 denotes a storage vessel that stores a sulfuric acid solution; Reference Numeral 33 denotes an electrolysis device; and Reference Numeral 60 denotes an oxidant-concentration-monitoring device that is the apparatus for measuring the concentration of an oxidant according to the present invention.

A sulfuric acid solution contained in the storage vessel 32 is fed to the electrolysis device 33 through a pipe 36 provided with a pump 34 and a cooler 35 that are disposed therein. Peroxydisulfuric acid is produced by the electrolysis in the electrolysis device 33. The sulfuric acid solution containing peroxydisulfuric acid is returned to the storage vessel 32 through a pipe 38 provided with a vapor-liquid separator 37 disposed therein. The storage vessel 32 is provided with a pure water-feeding pipe 39 and a concentrated sulfuric acid-feeding pipe 40 that are connected to the storage vessel 32.

The sulfuric acid solution containing peroxydisulfuric acid which is contained in the storage vessel 32 is drawn through a pipe 42 provided with a pump 41 and fed to the cleaning device 30 through a filter 43, a preheater 44, a pipe 45, a heater 46, and a pipe 47. In the above process, feeding of the liquid to the storage vessel 31 is stopped. A waste cleaning liquid generated in the cleaning device 30 as a result of cleaning of an electronic material is discharged to the outside of the system through pipes 48 and 49. After the cleaning of an electronic material has been finished, the discharge of the waste cleaning liquid to the outside of the system is stopped and feeding of the liquid to the storage vessel 31 is started. The unused cleaning liquid is returned to the storage vessel 31 and passed to the storage vessel 32 with a pump 50 through a pipe 53 provided with a filter 51 and a cooler 52 that are disposed therein.

The pipe 45 through which the cleaning liquid is fed from the preheater 44 to the heater 46 is provided with a liquid-sampling pipe 54 branched from the pipe 45, through which part of the cleaning liquid is taken as a sample liquid. The liquid sampled through the pipe 54 which has been used for the measurement of the concentration of an oxidant in the oxidant-concentration-monitoring device 60 (e.g., the liquid contained in the separated-liquid return tank 4 included in the apparatus for measuring the concentration of an oxidant illustrated in FIG. 1) is returned to the preheater 44 disposed upstream of the liquid-sampling position through the pipe 55 as in FIG. 3.

Detecting the concentration of an oxidant in the cleaning liquid while cleaning is performed and controlling the concentration of the oxidant in the cleaning liquid as needed by using the apparatus for measuring the concentration of an oxidant according to the present invention as a component of the system for cleaning an electronic material as illustrated in FIGS. 3 and 4 makes it possible to achieve efficient cleaning with a cleaning liquid including an appropriate concentration of an oxidant.

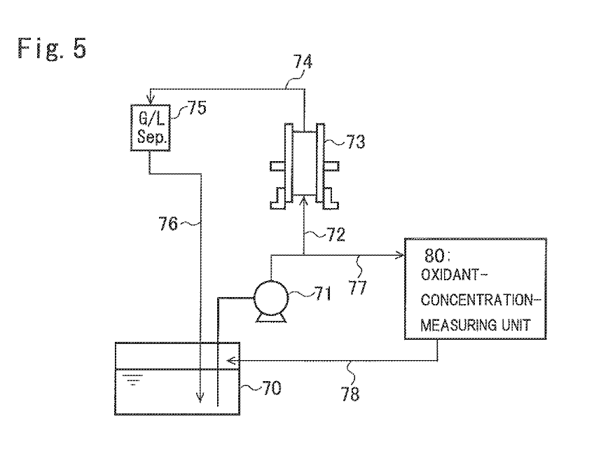

FIG. 5 illustrates an example where the apparatus for measuring the concentration of an oxidant according to the present invention is applied to a system for producing a cleaning liquid. In FIG. 5, a liquid that is to be electrolyzed is fed from a storage vessel 70 to an electrolysis cell 73 through a pipe 72 provided with a pump 71 disposed therein, and the resulting electrolyzed liquid is returned to the storage vessel 70 through a pipe 74, a vapor-liquid separator 75, and a pipe 76. The pipe 72 is provided with a pipe 77 branched from the pipe 72 at a position downstream of the pump 71, through which a sample liquid is taken from the pipe 72. The sample liquid taken from the pipe 72 is fed to an oxidant-concentration-measuring unit 80 that is the apparatus for measuring the concentration of an oxidant according to the present invention. The liquid that has been used for the measurement of the concentration of an oxidant (e.g., the liquid contained in the separated-liquid return tank 4 included in the apparatus for measuring the concentration of an oxidant illustrated in FIG. 1) is returned to the storage vessel 70 through a pipe 78.

As described above, the apparatus for measuring the concentration of an oxidant according to the present invention may be applied to not only a system for cleaning an electronic material but also a system for producing a cleaning liquid for electronic materials. In such a case, measuring the concentration of an oxidant in the cleaning liquid with the apparatus for measuring the concentration of an oxidant according to the present invention and controlling the operating conditions on the basis of the measurement results enable a cleaning liquid having a desired concentration of an oxidant to be produced.

### EXAMPLE

The present invention is described below more specifically with reference to Examples.

[Measurement of Concentration of Oxidant]

### Example I-1

The concentration of an oxidant in a sample liquid was measured with the apparatus for measuring the concentration of an oxidant which is illustrated in FIG. 1. The specifications of the measurement were as follows.

Sample liquid: Electrolyzed sulfuric acid solution (liquid produced by the electrolysis of an 85-weight % sulfuric acid solution; designed oxidant concentration: 2 or 6 g/L (as S₂O₈²⁻))

Decomposition section: The sample liquid was passed through a decomposition heater at a flow rate of 20 or 50 mL/min with a retention time of 12.5 minutes or 5 minutes. The sample liquid was heated to 180° C. or 200° C. in order to decompose the oxidant.

Measurement section: The flow rate of the sample liquid was measured with a liquid-flow meter disposed upstream of the decomposition section.

The flow rate of oxygen gas was measured with a gas-flow meter disposed downstream of the decomposition section.

The oxidant concentration in the sample liquid and the oxidant concentration in the treated liquid that had been subjected to vapor-liquid separation were measured by KI titration at positions upstream and downstream of the decomposition section, respectively. The concentration of the oxidant decomposed in the decomposition section and the decomposition percentage were determined from the difference in the concentration of an oxidant.

Hereinafter, the concentration of an oxidant in the sample liquid which was measured by KI titration is represented by A (g/L), and the concentration of an oxidant in the decomposed liquid (the treated liquid that had been subjected to vapor-liquid separation) measured by KI titration is represented by B (g/L). The concentration of the decomposed oxidant is determined as A−B (g/L), and the decomposition percentage is determined as {(A−B)/A}×100.

The concentration C of the oxidant decomposed in the decomposition section was determined from the measured flow rate of the sample liquid, the measured flow rate of the gas, and the oxidant decomposition percentage determined in the above measurement in which KI titration was used using the following expression.

Concentration of oxidant [g/L]=(Flow rate of oxygen gas [mL/min]×S₂O₈²⁻ molecular weight: 192×2)/(Flow rate of sample liquid [mL/min]×1×22.4×Decomposition percentage)

The error ratio between the concentration of the decomposed oxidant determined by KI titration, (A−B), and the concentration of the decomposed oxidant determined in the present invention, C, was calculated using the following expression.

Error ratio={(A−B)−C}/(A−B)×100

Table 1 summarizes the results (Run-1 to Run-6). It was confirmed that, under the conditions where the temperature of the sample liquid in the decomposition section was set to 200° C. and the retention time of the sample liquid in the decomposition section was set to 2 minutes, the error ratio between the concentration of the decomposed oxidant determined by KI titration, (A−B), and the concentration of the decomposed oxidant determined by the method for measuring oxygen gas according to the present invention, C, was 10% or less, that is, they agreed with each other sufficiently.

### Example I-2

Liquids prepared by dissolving a metal (Ti) in the sample liquids used in Run-5 and Run-6 of Example I-2 at a concentration of 500 ppm were subjected to the same operations as in Run-5 and Run-6 of Example I-2, respectively. Table 1 shows the results (Run-7 and Run-8).

It was confirmed also in Example I-2 that the error ratio between the concentration of the decomposed oxidant determined by KI titration, (A−B), and the concentration of the decomposed oxidant determined by the method for measuring oxygen gas according to the present invention, C, was 10% or less, that is, they agreed with each other sufficiently.

Thus, similar results were obtained regardless of the presence of the metal. This confirms that, even when a sample liquid includes a metal, it is possible to measure the concentration of an oxidant in the sample liquid by the method according to the present invention with accuracy without being affected by the metal.

TABLE 1

| | Liquid | Liquid | Designed | | | | Oxidant |
|---|---|---|---|---|---|---|---|
| | temperature | retention | oxidant | Flow rate | | Concentration | concentration in |
| | at outlet of | time in | concentration | of sample | Flow rate | of decomposed | sample liquid, A |
| | decomposition | decomposition | in sample liquid | liquid | of gas | oxidant, C | (g/L), Note: KI |
| Run | section (° C.) | section (min) | (g/L) | (mL/min) | (mL/min) | (g/L) | value |
| 1 | 180 | 12.5 | 2 | 20 | 1.62 | 1.4 | 2.0 |
| 2 | 180 | 12.5 | 6 | 20 | 5.20 | 4.5 | 6.0 |
| 3 | 200 | 12.5 | 2 | 20 | 2.19 | 1.9 | 2.0 |
| 4 | 200 | 12.5 | 6 | 20 | 6.47 | 5.6 | 6.0 |
| 5 | 200 | 5 | 2 | 50 | 4.91 | 1.7 | 2.0 |
| 6 | 200 | 5 | 6 | 50 | 16.16 | 5.6 | 6.0 |
| 7 | 200 | 12.5 | 2 | 20 | 2.08 | 1.8 | 2.0 |
| 8 | 200 | 12.5 | 6 | 20 | 6.24 | 5.4 | 6.0 |

| | Oxidant | | | |
|---|---|---|---|---|
| | concentration | | | |
| | in sample | | | Error ratio be0tween |
| | liquid after | Concentration | | the present invention |
| | decomposition, | of decomposed | Decomposition | and KI value |
| | B (g/L), Note: | oxidant, A − B | percentage | {(A − B) − C}/ |
| Run | KI value | (g/L) | (A − B)/A × 100 (%) | (A − B) × 100 (%) |
| 1 | 0.5 | 1.5 | 75 | 6.7 |
| 2 | 1.4 | 4.6 | 77 | 2.2 |
| 3 | 0.0 | 2.0 | 100 | 5.0 |
| 4 | 0.2 | 5.8 | 97 | 3.4 |
| 5 | 0.2 | 1.8 | 90 | 5.6 |
| 6 | 0.4 | 5.6 | 93 | 0.0 |
| 7 | 0.1 | 1.9 | 95 | 5.3 |
| 8 | 0.2 | 5.8 | 97 | 6.9 |

[Comparison of Start-Up Time]

Tests were conducted using the apparatus for measuring the concentration of an oxidant illustrated in FIG. 1 and the apparatus for measuring the concentration of an oxidant illustrated in FIG. 6 in order to compare the start-up time required when the concentration of an oxidant is measured as in Examples I-1 and I-2.

### Example II-1

The apparatus for measuring the concentration of an oxidant illustrated in FIG. 1 was used for the measurement.

(1) During Normal Operation

A persulfuric acid solution (prepared by the electrolysis of a 92-weight % sulfuric acid solution; designed oxidant concentration: 2 g/L (as H₂S₂O₈)) fed from an ESA unit as a sample liquid was passed through a pyrolyzer 1 having a volume of 100 mL at a flow rate of 20 mL/min with a retention time of 5 minutes. The sample liquid was heated to 200° C. in order to decompose the oxidant. The concentration of the oxidant determined from the concentration of the oxygen gas was 2 g/L.

(2) During Replacement of Liquid in ESA Unit

Heating of the pyrolyzer 1 and feeding of the persulfuric acid solution from the ESA unit were stopped in order to pause the measurement.

(3) After Replacement of Liquid in ESA Unit had been Finished

Feeding of the liquid from the ESA unit was restarted. After the pyrolyzer 1 had been filled with the sample liquid, performing heating at 200° C. was restarted.

The amount of time from when feeding of the liquid was restarted to when the flow rate of the oxygen gas was stabilized, that is, the start-up was completed, was 30 minutes.

### Example II-2

The apparatus for measuring the concentration of an oxidant illustrated in FIG. 1 was used for the measurement.

(1) During Normal Operation

A persulfuric acid solution (prepared by the electrolysis of a 92-weight % sulfuric acid solution; designed oxidant concentration: 10 g/L (as H₂S₂O₈)) fed from an ESA unit as a sample liquid was passed through a pyrolyzer 1 having a volume of 100 mL at a flow rate of 20 mL/min with a retention time of 5 minutes. The sample liquid was heated to 200° C. in order to decompose the oxidant. The concentration of the oxidant determined from the concentration of the oxygen gas was 10 g/L.

(2) During Replacement of Liquid in ESA Unit

Heating of the pyrolyzer 1 and feeding of the persulfuric acid solution from the ESA unit were stopped in order to pause the measurement.

(3) After Replacement of Liquid in ESA Unit had been Finished

Feeding of the liquid from the ESA unit was restarted. After the pyrolyzer 1 had been filled with the sample liquid, performing heating at 200° C. was restarted.

The amount of time from when feeding of the liquid was restarted to when the flow rate of the oxygen gas was stabilized, that is, the start-up was completed, was 45 minutes.

### Example II-3

The apparatus for measuring the concentration of an oxidant illustrated in FIG. 1 was used for the measurement.

(1) During Normal Operation

A persulfuric acid solution (prepared by the electrolysis of a 92-weight % sulfuric acid solution; designed oxidant concentration: 10 g/L (as H₂S₂O₈)) fed from an ESA unit as a sample liquid was passed through a pyrolyzer 1 having a volume of 100 mL at a flow rate of 50 mL/min with a retention time of 5 minutes. The sample liquid was heated to 200° C. in order to decompose the oxidant. The concentration of the oxidant determined from the concentration of the oxygen gas was 10 g/L.

(2) During Replacement of Liquid in ESA Unit

Heating of the pyrolyzer 1 and feeding of the persulfuric acid solution from the ESA unit were stopped in order to pause the measurement.

(3) After Replacement of Liquid in ESA Unit had been Finished

Feeding of the liquid from the ESA unit was restarted. After the pyrolyzer 1 had been filled with the sample liquid, performing heating at 200° C. was restarted.

The amount of time from when feeding of the liquid was restarted to when the flow rate of the oxygen gas was stabilized, that is, the start-up was completed, was 25 minutes.

### Example II-4

The apparatus for measuring the concentration of an oxidant illustrated in FIG. 6 was used for the measurement.

(1) During Normal Operation

A persulfuric acid solution (prepared by the electrolysis of a 92-weight % sulfuric acid solution; designed oxidant concentration: 2 g/L (as H₂S₂O₈)) fed from an ESA unit as a sample liquid was passed through a pyrolyzer 1 having a volume of 100 mL at a flow rate of 20 mL/min with a retention time of 5 minutes. The sample liquid was heated to 200° C. in order to decompose the oxidant. The concentration of the oxidant determined from the concentration of the oxygen gas was 2 g/L.

(2) During Replacement of Liquid in ESA Unit

Feeding of the persulfuric acid solution from the ESA unit was stopped. Simultaneously, a replacement liquid (a persulfuric acid solution containing 2 g/L (as H₂S₂O₈) of an oxidant) was fed from the replacement-liquid tank 8 at 20 mL/min. In the above process, heating of the pyrolyzer 1 was continued such that the temperature of the pyrolyzer 1 was maintained to be 200° C.

(3) After Replacement of Liquid in ESA Unit had been Finished

Feeding of the liquid from the ESA unit was restarted, while feeding of the liquid from the replacement-liquid tank 8 was stopped. The temperature of the pyrolyzer 1 was still maintained to be 200° C. The amount of time from when feeding of the liquid was restarted to when the flow rate of the oxygen gas was stabilized, that is, the start-up was completed, was 15 minutes.

### Example II-5

The apparatus for measuring the concentration of an oxidant illustrated in FIG. 6 was used for the measurement.

(1) During Normal Operation

A persulfuric acid solution (prepared by the electrolysis of a 92-weight % sulfuric acid solution; designed oxidant concentration: 10 g/L (as H₂S₂O₈)) fed from an ESA unit as a sample liquid was passed through a pyrolyzer 1 having a volume of 100 mL at a flow rate of 20 mL/min with a retention time of 5 minutes. The sample liquid was heated to 200° C. in order to decompose the oxidant. The concentration of the oxidant determined from the concentration of the oxygen gas was 10 g/L.

(2) During Replacement of Liquid in ESA Unit

Feeding of the persulfuric acid solution from the ESA unit was stopped. Simultaneously, a replacement liquid (a persulfuric acid solution containing 10 g/L (as H₂S₂O₈) of an oxidant) was fed from the replacement-liquid tank 8 at 20 mL/min. In the above process, heating of the pyrolyzer 1 was continued such that the temperature of the pyrolyzer 1 was maintained to be 200° C.

(3) After Replacement of Liquid in ESA Unit had been Finished

Feeding of the liquid from the ESA unit was restarted, while feeding of the liquid from the replacement-liquid tank 8 was stopped. The temperature of the pyrolyzer 1 was still maintained to be 200° C. The amount of time from when feeding of the liquid was restarted to when the flow rate of the oxygen gas was stabilized, that is, the start-up was completed, was 15 minutes.

### Example II-6

The apparatus for measuring the concentration of an oxidant illustrated in FIG. 6 was used for the measurement.

(1) During Normal Operation

A persulfuric acid solution (prepared by the electrolysis of a 92-weight % sulfuric acid solution; designed oxidant concentration: 10 g/L (as H₂S₂O₈)) fed from an ESA unit as a sample liquid was passed through a pyrolyzer 1 having a volume of 100 mL at a flow rate of 50 mL/min with a retention time of 5 minutes. The sample liquid was heated to 200° C. in order to decompose the oxidant. The concentration of the oxidant determined from the concentration of the oxygen gas was 10 g/L.

(2) During Replacement of Liquid in ESA Unit

Feeding of the persulfuric acid solution from the ESA unit was stopped. Simultaneously, a replacement liquid (a persulfuric acid solution containing 10 g/L (as H₂S₂O₈) of an oxidant) was fed from the replacement-liquid tank 8 at 50 mL/min. In the above process, heating of the pyrolyzer 1 was continued such that the temperature of the pyrolyzer 1 was maintained to be 200° C.

(3) After Replacement of Liquid in ESA Unit Had Been Finished

Feeding of the liquid from the ESA unit was restarted, while feeding of the liquid from the replacement-liquid tank 8 was stopped. The temperature of the pyrolyzer 1 was still maintained to be 200° C. The amount of time from when feeding of the liquid was restarted to when the flow rate of the oxygen gas was stabilized, that is, the start-up was completed, was 6 minutes.

Table 2 summarizes the results.

TABLE 2

| | | | Amount of time |
|---|---|---|---|
| | | | required for |
| | Oxidant concentration | Flow rate of | completion of |
| | in sample liquid | sample liquid | start-up |
| Run | (g/L) | (mL/min) | (min) |
| Example II-1 | 2 | 20 | 30 |
| Example II-2 | 10 | 20 | 45 |
| Example II-3 | 10 | 50 | 25 |
| Example II-4 | 2 | 20 | 15 |
| Example II-5 | 10 | 20 | 15 |
| Example II-6 | 10 | 50 | 6 |

The results shown in Table 2 confirm that continuing heating of the pyrolyzer by feeding the replacement liquid to the pyrolyzer while feeding of the sample liquid was stopped markedly reduced the amount of time required for the start-up.

Although the present invention has been described in detail with reference to particular embodiments, it is apparent to a person skilled in the art that various modifications can be made therein without departing from the spirit and scope of the present invention.

The present application is based on Japanese Patent Application No. 2015-005079 filed on Jan. 14, 2015, and Japanese Patent Application No. 2016-000821 filed on Jan. 6, 2016, which are incorporated herein by reference in their entirety.

### REFERENCE SIGNS LIST

1 PYROLYZER
2 VAPOR-LIQUID SEPARATOR
3 SEPARATED-LIQUID COOLER
4 SEPARATED-LIQUID RETURN TANK
5 GAS COOLER
6 COMPUTING ELEMENT
7 DEMISTER
8 REPLACEMENT-LIQUID TANK
11F LIQUID-FLOW METER
17F GAS-FLOW METER
20 STORAGE VESSEL
22 CLEANING MACHINE
28 OXIDANT-CONCENTRATION-MEASURING UNIT
30 SINGLE-WAFER CLEANING DEVICE
31,32 STORAGE VESSEL
33 ELECTROLYSIS DEVICE
44 PREHEATER
46 HEATER
60 OXIDANT-CONCENTRATION-MONITORING DEVICE
70 STORAGE VESSEL
73 ELECTROLYSIS CELL
75 VAPOR-LIQUID SEPARATOR
80 OXIDANT-CONCENTRATION-MEASURING UNIT

1. A method for measuring a concentration of an oxidant in a sample liquid used as a cleaning liquid in a process of cleaning an electronic material, the method comprising:
decomposing at least part of an oxidant included in the sample liquid;
measuring an amount of released gas generated by decomposition of the oxidant, the released gas including oxygen gas; and
determining the concentration of the oxidant in the sample liquid based on the amount of the released gas.

2. The method for measuring a concentration of an oxidant according to claim 1, wherein the sample liquid is successively introduced to decomposing device for decomposing the oxidant, the decomposing device discharging the released gas including oxygen gas, and wherein the concentration of the oxidant in the sample liquid is determined from a flow rate of the sample liquid and a flow rate of the released gas.

3. The method for measuring a concentration of an oxidant according to claim 1, wherein the oxidant is decomposed by using at least one selected from heating, ultraviolet radiation, ultrasound, and a catalyst.

4. The method for measuring a concentration of an oxidant according to claim 3, wherein the sample liquid is a sulfuric acid solution including an oxidant, the concentration of sulfuric acid in the sulfuric acid solution being 85% by weight or more, and wherein the oxidant is decomposed by performing heating at 150° C. or more.

5. The method for measuring a concentration of an oxidant according to claim 1, wherein, subsequent to decomposing the oxidant included in the sample liquid, the released gas is subjected to vapor-liquid separation, and an amount of resulting separated gas is measured.

6. The method for measuring a concentration of an oxidant according to claim 5, wherein, subsequent to the vapor-liquid separation, vapor and mist included in the separated gas are removed by cooling the gas.

7. The method for measuring a concentration of an oxidant according to claim 6, wherein the vapor and mist included in the separated gas are removed by passing the separated gas through a layer filled with a filler.

8. The method for measuring a concentration of an oxidant according to claim 1, wherein the sample liquid includes at least one selected from a soluble organic substance, undissolved SS, and metal ions.

9. The method for measuring a concentration of an oxidant according to claim 1, wherein part of the cleaning liquid fed to the process of cleaning an electronic material is taken, as a sample liquid, from a liquid-feeding system for feeding the cleaning liquid, and, subsequent to measuring the concentration of the oxidant in the sample liquid, the sample liquid is returned to the liquid-feeding system at a position upstream of a position at which the sample liquid is taken from the liquid-feeding system.

10. The method for measuring a concentration of an oxidant according to claim 1, wherein, in the process of cleaning an electronic material, a waste cleaning liquid is recycled and reused as the cleaning liquid.

11. The method for measuring a concentration of an oxidant according to claim 1, the method including a measurement step in which the concentration of the oxidant in the sample liquid is measured while the sample liquid is successively introduced to the device for decomposing the oxidant; and a non-measurement step in which introduction of the sample liquid to the device for decomposing the oxidant is stopped, wherein, in the non-measurement step, a replacement liquid is introduced to the device for decomposing the oxidant.

12. The method for measuring a concentration of an oxidant according to claim 11, wherein the device for decomposing the oxidant performs heating in order to decompose the oxidant and continues the heating even in the non-measurement step.

13. The method for measuring a concentration of an oxidant according to claim 11, wherein a difference in liquid composition between the replacement liquid and the sample liquid is 30% or less of a liquid composition of the sample liquid.

14. An apparatus for measuring a concentration of an oxidant in a sample liquid used as a cleaning liquid in a process of cleaning an electronic material, the apparatus comprising:
oxidant-decomposing device for decomposing at least part of the oxidant included in a sample liquid;
a released-gas-measuring device for measuring an amount of released gas generated by decomposition of the oxidant, the released gas including oxygen gas; and
a computing device for determining the concentration of the oxidant in the sample liquid based the amount of the released gas measured by the released-gas-measuring device.

15. The apparatus for measuring a concentration of an oxidant according to claim 14, the apparatus further comprising:
an introduction pipe through which the sample liquid is introduced to the oxidant-decomposing device;
a liquid-flow meter disposed in the introduction pipe;
an exhaust pipe through which released gas generated in the oxidant-decomposing device is exhausted; and
a gas-flow meter disposed in the exhaust pipe, the computing device determining the concentration of the oxidant based on a value measured with the liquid-flow meter and a value measured with the gas-flow meter.

16. The apparatus for measuring a concentration of an oxidant according to claim 14, wherein the oxidant-decomposing device employs at least one decomposition system selected from heating, ultraviolet radiation, ultrasound, and a catalyst.

17. The apparatus for measuring a concentration of an oxidant according to claim 14, wherein the sample liquid is a sulfuric acid solution including an oxidant, the concentration of sulfuric acid in the sulfuric acid solution being 85% by weight or more, and wherein the oxidant-decomposing device performs heating at 150° C. or more.

18. The apparatus for measuring a concentration of an oxidant according to claim 14, the apparatus further comprising a vapor-liquid separation device in which the released gas discharged from the oxidant-decomposing device is subjected to vapor-liquid separation, a separated gas produced in the vapor-liquid separation device being fed to the released-gas-measuring means.

19. The apparatus for measuring a concentration of an oxidant according to claim 18, the apparatus further comprising a gas-purifying device for removing vapor and mist included in the separated gas produced in the vapor-liquid separation device by cooling the separated gas, gas purified in the gas-purifying device being fed to the released-gas-measuring device.

20. The apparatus for measuring a concentration of an oxidant according to claim 19, wherein the gas-purifying device includes a layer filled with a filler.

21. The apparatus for measuring a concentration of an oxidant according to claim 18, the apparatus further comprising a device for cooling a separated liquid produced in the vapor-liquid separation device.

22. The apparatus for measuring a concentration of an oxidant according to claim 14, the apparatus further comprising:
a replacement-liquid tank for storing a replacement liquid introduced to the oxidant-decomposing device instead of the sample liquid; and
a first introduction pipe through which the replacement liquid stored in the replacement-liquid tank is introduced to the oxidant-decomposing device.

23. The apparatus for measuring a concentration of an oxidant according to claim 22,
wherein the oxidant-decomposing device decomposes the oxidant by performing heating,
wherein the apparatus further comprises a switching device with which the introduction of the liquid is switched between a second introduction pipe through which the sample liquid is introduced to the oxidant-decomposing device and the first introduction pipe through which the replacement liquid stored in the replacement-liquid tank is introduced to the oxidant-decomposing device, and
wherein the oxidant-decomposing device continues heating even while the replacement liquid is introduced to the oxidant-decomposing device.

24. The apparatus for measuring a concentration of an oxidant according to claim 22, wherein the difference in liquid composition between the replacement liquid and the sample liquid is 30% or less of the liquid composition of the sample liquid.

25. A system for cleaning an electronic material, the system comprising:
a device for cleaning an electronic material;
a cleaning-liquid-feeding device for feeding a cleaning liquid to the cleaning device;
a liquid-sampling device for taking part of the cleaning liquid as a sample liquid from the cleaning-liquid-feeding device; and
an oxidant-concentration-measuring device for that measuring a concentration of an oxidant in the sample liquid taken by the liquid-sampling device, the oxidant-concentration-measuring device including the apparatus for measuring a concentration of an oxidant according to claim 14.

26. The system for cleaning an electronic material according to claim 25, the system further comprising a sample-liquid-returning device that returns, subsequent to the measurement of the concentration of an oxidant by the oxidant-concentration-measuring device, the sample liquid taken by the liquid-sampling device to a position upstream of a position at which the sample liquid is taken from the cleaning-liquid-feeding device.

27. The system for cleaning an electronic material according to claim 26, wherein the oxidant-concentration-measuring device includes the apparatus for measuring a concentration of an oxidant according to claim 21, and wherein the system further comprises a vessel that stores a liquid cooled by the device for cooling the separated liquid, the liquid stored in the storage vessel being returned by the sample-liquid-returning device.

28. The system for cleaning an electronic material according to claim 25, the system further comprising:
a recycling device for recycling a waste cleaning liquid that has been used for cleaning in the cleaning device; and
a circulation device for feeding a liquid recycled in the recycling device to the cleaning device, the liquid being reused as a cleaning liquid.
